(19) United States
(12) Patent Application Publication
(10) Pub. No.: US 2004/0240272 A1
(43) Pub. Date: Dec. 2, 2004

(54) Preset data storage for personal digital device

(76) Inventors: Hon-Wai Ng, Hsinchu Hsien (TW); Li-Pai Chen, Taipei City (TW); Chu-Cheng Liang, Hsinchu Hsien (TW)

Correspondence Address: BIRCH STEWART KOLASCH & BIRCH, PO BOX 747, FALLS CHURCH, VA, 22040-0747, US

(21) Appl. No.: 10/449,603

(22) Filed: Jun. 2, 2003

(51) Int. Cl. G11C 16/04

(52) U.S. Cl. 365/185.33

(57) ABSTRACT

The personal digital device of the present invention comprises a flash memory that comprises one or more than one signal marks representing related preset parameter(s) or information for the player in the free space, the preset parameter(s) or information is, for example, music, volume, vision, playing sequence and so on. Thus when the user turns on the player, the controller within the player identifies and retrieves the signal mark stored in the free space of the flash memory, and retrieve the preset parameters or information previously stored or set as the signal mark, and therefore the player is capable of reproducing preset parameters or information. Thus, the inconvenience of setting, for example, sound, volume of the sound, vision and the like, each time the player is turned on can be effectively eliminated.

### BACKGROUND OF THE INVENTION

1. The Field of the Invention

The present invention relates to a personal digital device such as digital cameras, both still and video, so-called personal assistants, hand-held computers, MP3 players, cell phones, pagers, and the like, and more particularly relates to a preset data storage for personal digital device that is capable of saving or storing the parameters such as sound, vision or audio data previously set can be retrieved and reproduced whenever the preset data storage player turned on.

2. Description of the Related Art

The conventional MP3 player does not have the function for storing preset parameters or information of playing music, for instance, volume, playing sequence and so on, thus the user's preset data will be erased each time the power of the MP3 player is turned off, and therefore the user has to set the parameters or the information each time when the power of the MP3 player is turned as it returns to the initialization status. Thus this causes substantial inconvenience to the users.

Generally, one way of solving the above problem is to save the user's preset data separately into a memory device such as a SRAM or an EEPROM. Though use of SRAM or EEPROM can overcome the conventional problem, but however the cost of SRAM is high and also power consumption is substantially high as a certain minimum level of power supply is required for the player to function memory storage normally. Even though the EEPROM does not involve the continuous power consumption, the cost for the installation thereof is still considerable. Accordingly, it is highly desirable to further improve the conventional technology to overcome the above defects.

### SUMMARY OF THE INVENTION

Accordingly, in the view of the foregoing, the present inventor makes a detailed study of related art to evaluate and consider, and uses years of accumulated experience in this field, and through several experiments, to create a new personal digital device that is capable of storing the preset parameters or information, and capable of identifying and retrieving the preset parameters or the information whenever the personal digital device is turned on so that the inconvenience of setting the parameters or information each time the personal digital device can be effectively eliminated. The present invention provides an innovated cost effective personal digital device capable of storing the preset parameters or information.

In accordance with the above objects and other advantages of the present invention, a preset data storage for personal digital device capable of saving the preset parameters or information such as music, volume, vision or audio data. Further, the personal digital device of the present invention does not require a memory chip such as SRAM or EEPROM for storing the preset data, and therefore incurs no extra manufacturing cost.

According to one aspect of the present invention, the personal digital device of the present invention comprises a flash memory that comprises one or more than one signal marks representing related preset parameter(s) or information for the player in the free space, the preset parameter(s) or information is, for example, music, volume, vision, playing sequence and so on. Thus when the user turns on the player, the controller within the player identifies and retrieves the signal mark stored in the free space of the flash memory, and retrieve the preset parameters or information previously stored or set as signal mark(s), and therefore the personal digital device is capable of reproducing preset parameters or information. Thus, the inconvenience of setting, for example, sound, volume of the sound, vision and the like, each time the player is turned on can be effectively eliminated.

### BRIEF DESCRIPTION OF THE DRAWING

For a more complete understanding of the present invention, reference will now be made to the following detailed description of preferred embodiments taken in conjunction with the accompanying drawings, in which:

FIG. 1 is a circuit layout of the personal digital device of the present invention;

FIG. 2 illustrates the arrangement of the free space of the flash memory of the personal digital device of the present invention;

FIG. 3 shows the aspect of the marks in the free space of the flash memory of the personal digital device present invention; and

FIG. 4 illustrates the operation process flow chart of the personal digital device of the present invention.

### DETAILED DESCRIPTION OF PREFERRED EMBODIMENTS

Reference will be made in detail to the preferred embodiments of the invention, examples of which are illustrated in the accompanying drawings. Wherever possible, the same reference numbers are used in the drawings and the description to refer to the same or like parts.

The present invention present invention provides a preset data storage for personal digital device that does not rely upon memory chip such as SRAM or EEPROM for saving and storing the preset data, and therefore incur no extra cost, instead the personal digital device of the present invention uses the free space of a flash memory to store the preset data, for example, sound or audio data, vision and the like, previously input by the user. The following simply demonstrates the embodiments of the present invention that uses signal marks and stores in the free spaces of the flash memory, but however the following is not intended to limit the scope of the invention.

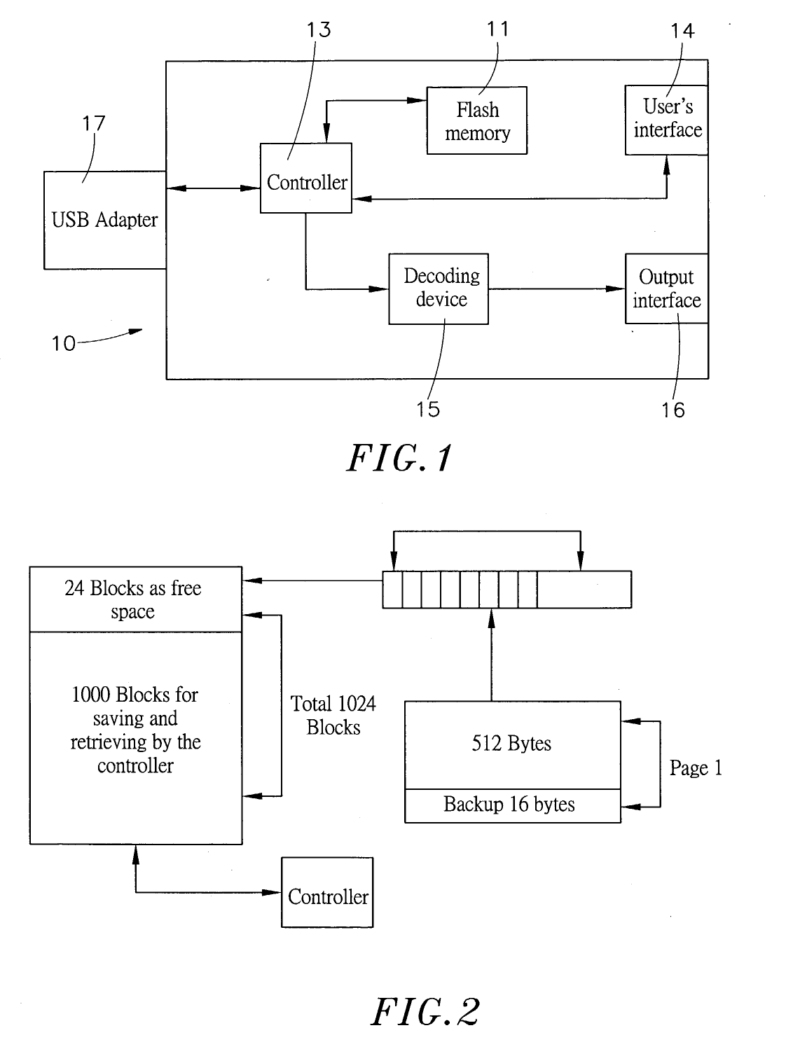

Referring to FIG. 1, the personal digital device 10 of the present invention comprises a flash memory 11 having a mark representing a preset data of personal digital device 10, for example, music, volume of sound, playing sequence and so on, stored in the free space of the flash memory 11. Thus when the user turns the power of the personal digital device 10 on, the controller 13 of the personal digital device 10 is capable of identifying and retrieving the marks of the flash memory 11, and therefore this makes it possible to check into the free space of the flash memory 11 according to the marks for retrieving the preset data. Thus, this in turn enables the controller 13 to reproduce sound, vision or audio data that were previously input by the user. Therefore, each time the user turns on the personal digital device 10, the personal digital device 10 is capable of reproducing the sound, vision or audio data according to the data previously set by the user and therefore the inconvenience of setting the data each time the player is turned on can be effectively eliminated.

As shown in FIG. 1, the personal digital device 10 also comprises a user's interface 14, a decoding device 15, an output interface 16 and an USB adaptor 17. The user's interface 14 connects with a plurality of input keys (not shown) and the controller 13 allows the user to input the parameter settings such as music, volume of the sound, vision or audio data and the like in the form of signal marks. The controller 13 stores the signal marks into the free space of the flash memory 11. And the decoding device 15 connects with the controller 13 and the output interface 16. The decoding device 15 decodes the preset parameters such as music, volume of the sound, vision or audio data stored in the controller 13 and output the decoded data through a output device, for example the sound can be output through the earphones, speaker and so on, that is connected to the output interface 16. Furthermore, the personal digital device 10 can be connected to a computer through the USB adaptor 17 for signals communication.

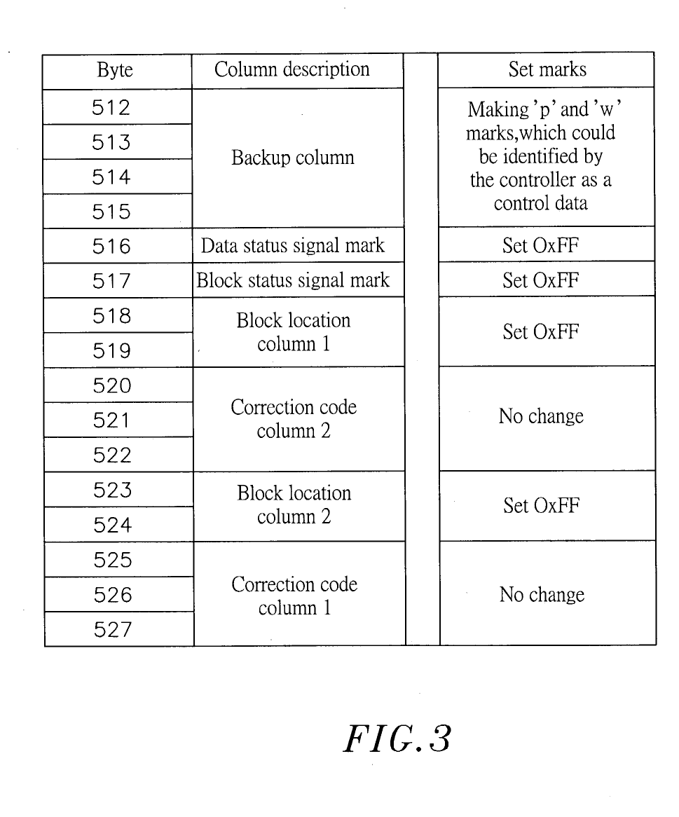

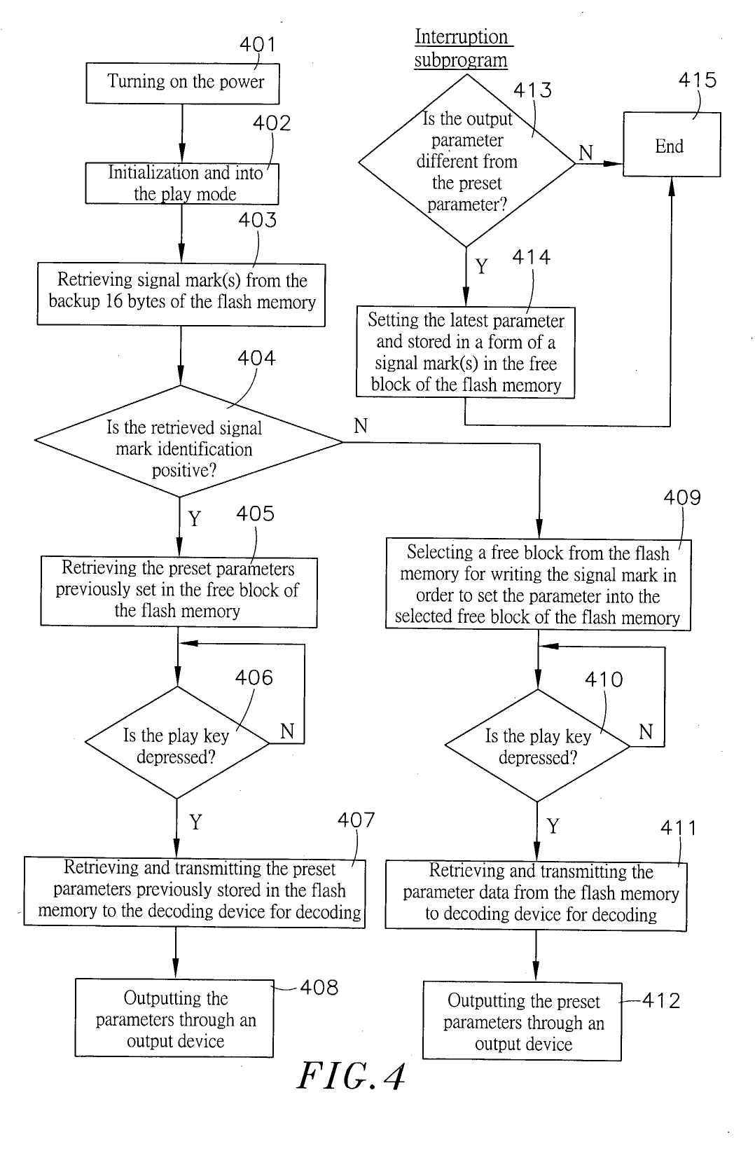

Further referring to FIGS. 2 and 3, the storage unit of the flash memory is in a form of zones, blocks, pages, wherein one zone constitutes 1024 blocks, one block constitutes 32 pages and one page constitutes 512 bytes, additionally with 16 backup bytes (1 byte=8 bits). The usage of the storage space of the general flash memory is about 1000 blocks, and the remaining of 24 blocks is used as free space. The present invention uses one of the free blocks for storing the preset parameters in the form of signal marks, such as music, volume of the sound, vision and audio (shown as FIG. 3) that can be identified and retrieved whenever the preset data storage player is turned on so that the preset sound, sound volume, vision or audio data, can be reproduced without requiring the need for resetting these parameters. In a preferred embodiment Word (2 bytes) may be used for storing the volume and playing sequence, the backup 16 bytes may be used for making related signal marks and storing the signal marks into the backup 16 bytes that is recognizable by the controller 13 as a control data. Accordingly the free block into which the sound, vision and audio playing data are preset can be tracked in order to reproduce the sound, vision and audio data that were previously set by the user.

Referring to FIGS. 1 and 4, the actual operation process of the personal digital device 10 of the present invention is described as follows. The first step (401) of the operation process begins with turning on the power of the personal digital device 10. Next, the process proceeds to step (402) in which the personal digital device 10 proceeds with the initialization and eventually into the play mode. Next, the process proceeds to step (403) in which the controller 13 of the personal digital device 10 retrieves signal mark(s) from the backup 16 bytes of the flash memory 11. Next, the process proceeds with step (404) which is a decision making step in which the retrieved signal mark(s) is/are identified, if the signal mark(s) identification is/are positive, the process proceeds to step (405), and if the identification of the signal mark(s) is/are negative, then the process skips to step (409). In step (405) the preset parameters such as music, volume of the sound, vision or audio data previously set represented by the signal mark(s) is/are retrieved. Then, the process proceeds to step (406) which is a decision making step in which if the user presses the play key, the process further proceed to step (407) if not the process remains in step (406). In step (407) the preset parameters such as music, volume of the sound, vision or audio data previously stored in the flash memory 11 are retrieved and transmitted to decoding device 15 for decoding. Then the process proceeds with step (408) in which the parameters such as music, volume of the sound, vision or audio data are output by an output device that is connected with the output interface 16. Then, the process proceeds to step (409) in which the controller 13 of the personal digital device 10 selects a free block from the flash memory 11 for writing the signal mark in order to set, for example, the parameter of the music, volume of the sound, vision or audio data into the selected free block of the flash memory 11, then the initiation value of the personal digital device 10 is reset so that the settings are retrievable and the setting of parameters can continue. Next, the process proceeds with step (410) in which whether or not the play key is pressed is identified, if the play key is pressed, the process proceeds to step (411), if not, the process remains in step (410). In step (411), the sound, vision or audio data from the flash memory 11 is retrieved and transmitted to decoding device 15 of the personal digital device 10 for decoding. Then, the process proceeds to step (412) in which the preset parameters such as music, volume of the sound, vision or audio data, is output by an output device connected with output interface 16.

Furthermore, when the controller 13 of the personal digital device 10 identifies that the preset parameters such as music, volume of the sound, vision or audio data is different from that of the previously set in step (413) in which the output parameter is identified to verify whether or not is different from the preset parameter data, if the identification is yes, then the process proceeds to step (414), if not, then the process skips to step (415). In step (414) the latest parameter is set and stored in a form of a signal mark(s) in the free block of the flash memory 11. The process ends in step (415).

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What the invention claimed is:

1. A preset data storage for personal digital device, the personal digital device comprising:
a flash memory having one or more than one signal marks representing one or more parameters stored in a free space of the flash memory; and
a controller, wherein when a user turns on said personal digital device, said controller identifies and retrieves said signal marks stored in the flash memory that was previously set by the user, so that the user need not set the parameters each time said personal digital device is turned on.

2. The preset data storage for personal digital device according to claim 1, further comprises a user's interface, said user's interface connects to a plurality of input keys as well as connects to said controller to enable the user to input the setting and mark that represent parameters, wherein said parameters comprises vision or audio data, and the controller stores said parameters into said free space of said flash memory.

3. The preset data storage for personal digital device according to claim 1, further comprises a decoding device connected to said controller and an output interface connected with said decoding device for decoding the parameters stored in said controller for outputting through an output device that is connected to the output interface.

4. The preset data storage for personal digital device according to claim 3, wherein said output device is an earphone.

5. The preset data storage for personal digital device according to claim 3, wherein said output device is a speaker.

6. The preset data storage for personal digital device according to claim 1, wherein said personal digital device is connected to a computer using an USB adaptor for signals communication.

7. The preset data storage for personal digital device according to claim 1, wherein said related parameter represent a volume of sound or a play sequence.
